(19) United States
(12) Patent Application Publication
(10) Pub. No.: US 2008/0188156 A1
(43) Pub. Date: Aug. 7, 2008

(54) Method for Structuring a Light Emitting Device

(76) Inventors: Dirk Buchhauser, Penang (MY); Christoph Gaerditz, Erlangen (DE); Karsten Heuser, Erlangen (DE); Wiebke Sarfert, Herzogenaurach (DE); Carsten Tschamber, Hamburg (DE); Oliver Weiss, Erlangen (DE)

Correspondence Address: FISH & RICHARDSON P.C., PO BOX 1022, MINNEAPOLIS, MN, 55440-1022, US

(21) Appl. No.: 12/023,578

(22) Filed: Jan. 31, 2008

(30) Foreign Application Priority Data
Jan. 31, 2007 (DE) 10 2007 004 890.6
Apr. 5, 2007 (DE) 10 2007 016 638.0

(51) Int. Cl. H01J 9/00; B23K 26/04

(52) U.S. Cl. 445/22; 219/121.78; 445/65

(57) ABSTRACT

Structuring electroluminescent organic semiconductor elements can be achieved by providing such an element with a first electrode, a second electrode, and an organic light-emitting layer arranged therebetween. For structuring, areas of the organic layer are selectively destroyed by means of thermal action on the organic layer. The areas destroyed by the thermal action, such as by a laser beam, show no electroluminescence during the operation of the organic semiconductor element. A structuring can thus also be achieved on large-area semiconductor elements in a flexible manner and at low cost.

### CROSS-REFERENCE TO RELATED APPLICATIONS

This patent application claims the priority of German patent applications 10 2007 004 890.6, filed Jan. 31, 2007, and 10 2007 016 638.0, filed Apr. 5, 2007, the disclosures of which are hereby incorporated by reference herein.

### BACKGROUND

The present disclosure relates to methods for structuring electroluminescent organic semiconductor elements, electroluminescent organic semiconductor elements and arrangements for structuring an element of this type.

The basic structure of an organic light-emitting diode comprises a pair of electrodes for charge-carrier injection into an organic light-emitting material arranged between the electrodes. Organic material between the electrodes, also called an OLED stack, can comprise several partial layers. The light generation takes place in one of these organic layers through charge-carrier recombination of holes with electrons. Further partial layers serve to transport the charge carriers or to limit possible exciton diffusion.

For charge-carrier injection the two electrodes are used as an anode or cathode, respectively. A conductive and transparent metal oxide, such as indium-doped tin oxide or indium-doped zinc oxide, is very often used as anode material. This is applied to a substrate carrier usually of glass or a transparent plastic film by means of depositing, sputtering or other processes. Depending on the organic material used, different production processes of the light-emitting layer are possible. With organic polymers, deposition processes with solvents through spinning, centrifuging, spraying or printing are frequently used. Solvent-free production methods such as vapor phase epitaxy or organic vapor phase deposition (OVPD) are often used.

To produce the cathode on the surface of the organic material deposited on the anode, metal compounds are applied as tunnel barriers, for example, LiF, CaF or elemental metal layers.

Because the organic materials as well as the electrodes used are often oxidizable by atmospheric oxygen or by water, the organic semiconductor elements are sealed after production by inert layers.

### SUMMARY

The increasing use of screens, which are examples for the application of OLEDs, such as in small and miniature consumer products, leads to increasing pressure to reduce the manufacturing costs for small screens of this type. Furthermore, there is a growing demand for illumination devices with a predetermined light pattern. Screens based on organic light-emitting diodes, so-called OLEDs, are becoming increasing popular in this context, because they contain a high luminosity simultaneous with a low power consumption and low manufacturing costs. Their great flexibility and usefulness in different possible applications as well as the feature of still rendering sufficient contrast even at low viewing angles, are further advantages for electroluminescent organic semiconductor elements.

To produce a structure for the electroluminescent organic semiconductor elements, for example, for the representation of a shape or a figure, at least one of the electrodes used is structured with the aid of photolithographic processes during the production process. For the production of screens with addressable pixels it is possible, for example, to structure the anode in columns and the cathode in rows such that the overlapping areas respectively specify separately addressable pixels. However, with screens or electroluminescent organic semiconductor elements for representing specific figures, this process is too complicated and leads to increased expenditure. There is thus a need to reduce the costs for the production process of electroluminescent organic semiconductor elements of this type and at the same time to guarantee the highest possible flexibility in structuring.

There is thus a need to reduce the costs for the production process of electroluminescent organic semiconductor elements of this type and at the same time to guarantee the highest possible flexibility in structuring.

A method for structuring electroluminescent organic semiconductor elements is described. An electroluminescent semiconductor element and an arrangement for structuring an electroluminescent organic semiconductor element is also described.

### BRIEF DESCRIPTION OF THE FIGURES

FIG. 1 shows an exemplary embodiment of an OLED device.

FIG. 2 shows an exemplary embodiment of an OLED device.

FIG. 3 shows a schematic representation of a system for structuring an organic layer in electroluminescent organic semiconductor elements.

### DETAILED DESCRIPTION

A method for structuring electroluminescent organic semiconductor elements is provided in which it is no longer the electrodes, but the light-emitting layer located between the electrodes that is structured after a production of the electroluminescent component. This is carried out in that areas of the organic layer are selectively destroyed by means of thermal action on the organic layer. The light-emitting layer is thus locally destroyed so that no further electroluminescence occurs. The element can appear to be destroyed if parts of a contiguous layer have a different composition than other parts of the same layer. The different composition can change the properties of the material in the layer, such as the destroyed portions having a lower ability to electroluminesce, a lower ability to carry charge or a higher resistance. The destruction of a local partial area can be understood to be a thermally induced chemical conversion of the organic compounds, which thus lose their property of luminescence. Alternatively, after a production of an unstructured electroluminescent organic semiconductor element, one or both electrodes can be structured by means of thermal action. The resistance of the electrodes in these partial areas is thus changed such that, greatly increased, it suppresses or reduces the charge-carrier injection at these locations.

The selective destruction of areas of the organic layer thus permits a flexible and essentially free generation of different types of structures for the electroluminescent organic semiconductor elements. For example, simple figures can thus be produced easily and without expensive photolithographic methods. In particular, the electrodes or the organic layer can be structured after a production of the component and a covering with a transparent protective layer to prevent an oxidation.

In one embodiment, the selective destruction by means of thermal action is carried out through a light beam focused on the organic layer. The light beam can be generated by a laser, which is a coherent beam. However, non-coherent light that is focused by a suitable optical system can also be used in the same manner.

Thus, in one embodiment the organic layer is selectively destroyed in areas by impinging external light on the organic layer. The use of a laser beam is thereby advantageous, since it can focus coherent light of a predefined wavelength on a small area and thus even small structures can be generated without errors. For the production of large-area structures, focused incoherent light beams can be used that act thermally on the desired areas such that electroluminescent behavior is destroyed. In another embodiment, at least one of the two electrodes is selectively destroyed in partial areas by thermal action after a production of the electroluminescent organic semiconductor element and the element is thus structured.

The laser beam or the light used can be in the visible wavelength spectrum or in the near-infrared spectrum. In particular it is expedient if at least one electrode of the electroluminescent organic semiconductor element is transparent to the light used and interacts with the electrode as little as possible. For the structuring, the light is focused through the electrode on the organic layer. Thus, on the one hand, a thermal heating up of the entire element is prevented and, on the other hand, a better structuring is achieved.

In some embodiments, in addition the transparent electrode or the transparent material that surrounds the light-emitting layer can be used for focusing the light on the areas of the organic layer. The light used for the process of selective destruction can be generated continuously or in a pulsed manner. For structuring it can be expedient to move the organic semiconductor element under the light beam, or the light beam over the organic layer. Likewise a combination of both is possible, whereby advantageously large-area structures of organic electroluminescent semiconductor elements can be produced in a production line.

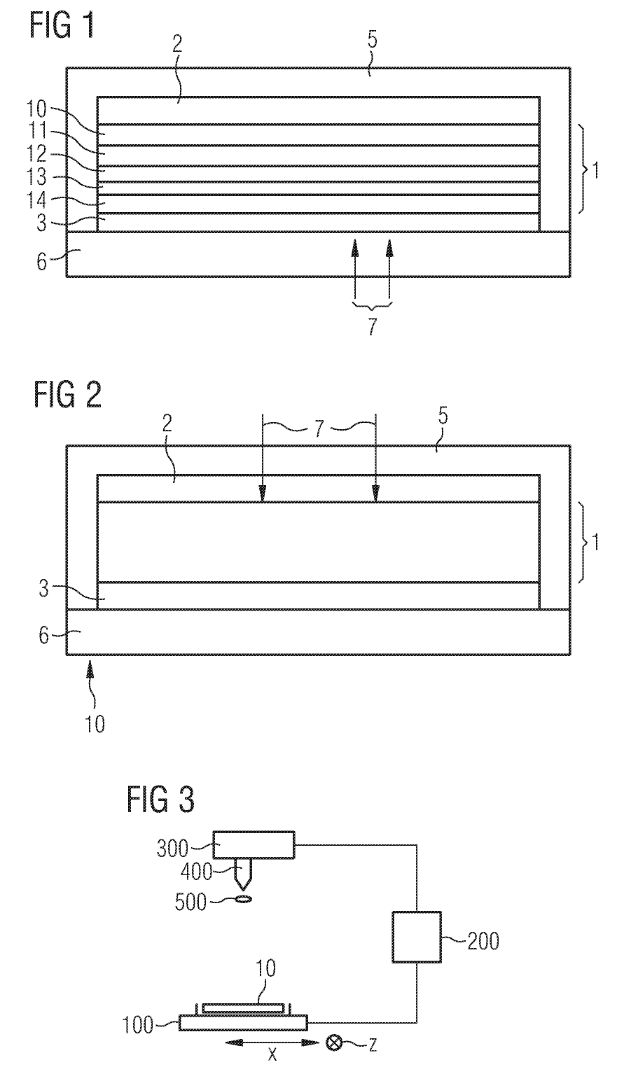

FIG. 1 shows an embodiment of an organic light-emitting diode (OLED), which is embodied as a so-called bottom-emitter with a transparent glass substrate 6 and a transparent first electrode 3. The electrode 3, which is an anode, comprises a layer of a transparent conductive metal oxide and is used for the laminar distribution of the charger-carriers on the OLED stack 1. Indium-doped tin oxide or indium-doped zinc oxide, for example, is used as material of the electrode 3. To improve conductivity this can be additionally “shunted” through thin line sections of highly conductive metal. The conductive metal oxide is deposited on the glass substrate 6 in a first production step. The thickness is approx. 1 μm but can also be thicker or thinner depending on the material. Typically it can be approx. 100 nm to 200 nm. Subsequently, the OLED stack 1 is produced on the anode 3.

The OLED stack 1 comprises a plurality of individual partial layers 10 through 14 of different organic materials. The layers 13 and 14 are used to transport the charge carriers provided by the anode into the light-emitting layers 11, 12 and to block the electrons initiated by the cathode 2 and hold them in the partial layers 11, 12. Furthermore, the partial layers 10, 13 and 14 limit exciton diffusion such that the recombination efficiency and thus photon generation are increased. In detail a first layer of 1-NATA is deposited on the anode 3. A layer of S-TAD is applied thereon. Subsequently three partial layers 12, 11 and 10 are deposited. The layers 11 and 12 comprise a light-emitting organic material. The materials used in the partial layers 11 and 12, however, are different and generate light of different wavelengths with a charge-carrier recombination. This results in a mixture of colored light being emitted from the OLED stack 1. With the use of three layers that generate light in the red, blue and green spectrum, white light can be produced.

In detail, the partial layer 12 is composed of the material SEB-010/SEB020 and generates photons in the blue range of the spectrum. The partial layer 11 comprises the material TMM-004:LR(ppy)3(15%) and is used to generate a green light. Light in the red spectrum could be generated, for example, by a partial layer with the material TMM-004:TER012. The partial layer 10, which is arranged over the layers 11 and 12, blocks the hole transport and improves the electron injection into the electroluminescent layers 11, 12. The arrangement shown of the partial layers 10 through 14 in the vertical arrangement is embodied as a so-called bottom-emitter with an emission direction of the radiated light towards the glass substrate 6. The arrangement of the light-emitting partial layers means that the photons generated in the partial layer 11 are not reabsorbed again through the partial layer 12.

For electron injection, finally the cathode 2 is applied on the uppermost partial layer 10 of the OLED stack 1. This is composed of a combination of a metal halide, for example, barium fluoride, calcium fluoride or lithium fluoride, and a conductive film of aluminum or silver deposited by evaporation to improve the lateral resistance. In addition, another reactive metal with low work function, such as barium, calcium or magnesium, can also be used as a cathode material. To prevent oxidation the entire OLED stack including the cathode 2 and anode 3 is covered by a protective coat 5. This can be composed of, for example, a second glass material or a plastic. Among other things, a thin-film encapsulation, which comprises several plies of a thin oxide layer and organic or polymer planarizing layers, is also suitable for the protective coat 5.

The production process shown here takes place without a complex structuring of the electrodes or of the individual layers of the OLED stack. In operation, the unstructured element glows uniformly. A structuring of the organic semiconductor diode or of the electroluminescent organic semiconductor element is now carried out with the aid of a focused laser beam 7, which is focused from outside through the glass substrate 6 and the electrode 3 onto the individual layers of the OLED stack 1. The wavelength of the laser beam 7 used is thereby selected such that it is absorbed as well as possible by the light-emitting partial layers 11 and 12. The high absorption in the partial layers 11 and 12 leads to a strong local thermal heating, through which the chemical compounds are broken down and new compounds are produced. The chemically converted material does not then have any luminescence in the irradiated partial areas. To put it in a simplified manner, the structure in the areas struck by the laser beam within the partial layers is destroyed. Accordingly, the areas of the partial layers 11 and 12 struck and heated by the laser beam no longer show any electroluminescence during the operation of the semiconductor element. In this manner an unstructured electroluminescent organic semiconductor element, the production process of which has already been completed, can be subsequently structured. For example, figures or characters can be burnt into the individual organic partial layers without this having to be already carried out during the production process with the aid of complex masks and photolithographic methods.

In the example shown here, in which both of the light-emitting partial layers 11 and 12 are selectively destroyed, it is also possible to direct the laser beam 7 in a wavelength-dependent manner onto only certain partial layers of the OLED stack. For example, a wavelength can be selected for the laser beam that is absorbed in only one of the partial layers of the OLED stack.

A first structure can thus be realized, for example, in the blue light-emitting partial layer 12, while different structures are generated in the other light-emitting partial layer 11. As a result, a production of different colored electroluminescent semiconductor elements is thus possible.

Alternatively, not only the light-producing layer, but also the layers 10 or 13 and 14 located above or beneath it can also be selectively destroyed. This is useful when focusing would be possible only to an inadequate extent or the layers absorb light of a specific wavelength particularly well. Also, instead of the organic layers, an electrode or even both electrodes can be structured by means of thermal action. This would largely save the organic layer itself from a selective destruction. Nevertheless, a structured light pattern is generated, which the electrodes in the damaged or destroyed areas no longer inject any charge-carriers into the stack. Likewise, different structures can be selectively produced in the different layers in order to also obtain complex patterns.

In another embodiment, it is also possible to use the glass substrate or the anode 3 for focusing the laser beam 7. Depending on a possible curvature of the glass substrate 6 or the electrode 3 or the material used, aberration effects during the structuring process can be utilized through the glass substrate 6 or the electrode 3.

FIG. 2 shows another embodiment of an OLED. In it, the OLED stack 1 comprises a single light-emitting layer. A thin reflecting metal layer is applied between the glass substrate 6 and the anode 3. This improves the electron injection and serves to reduce the resistance of the electrode 3 from the metal oxide. Additionally, light produced from the organic layers is reflected again in the desired radiation direction. The cathode 2 of a transparent material is deposited on the top of the OLED stack 1. The electroluminescent organic semiconductor element 10 is surrounded by a protective layer 5 of transparent material. In the operation of the organic light-emitting diode shown here, the light generated in the organic layer 1 is released through the top. This is therefore referred to as a top-emitter.

To structure the organic light-emitting diode in this embodiment a focused light beam is directed through the top of the protective layer 5 to the cathode 2 and the OLED stack 1. The local thermal heating leads to a destruction of the electroluminescence in these areas. The desired structure itself can be formed through a corresponding movement of the semiconductor element with respect to a fixed light beam 7 or through a movement of the light beam 7 to a fixed semiconductor element. Another possibility lies in burning the desired structure directly into the organic layer 1 with the aid of an optical imaging system. A diagrammatic representation for a system for using the different production methods is shown by FIG. 3.

The organic luminescent semiconductor element 10 is fixed on a movable positioning stage 100. The semiconductor element 10 can be a component of a larger-area wafer on which a plurality of semiconductor elements is arranged. The positioning stage 100 can also be part of a production line. The elements to be structured then move slowly through under the structuring device. Large-area organic semiconductor elements are thus easily structured.

The holder 100 can be moved freely perpendicular to the drawing plane with respect to the x direction as well as to the z direction. A movement of the holder 10 is carried out, for example, via piezoelectric elements in the case of a manufacture of the smallest possible structures or with the aid of precise stepper motors, if large-area semiconductor elements are structured. To control the movement the holder 100 is connected to a computer 200 and a control device. The system further has a second positioning device 300, which is operatively engaged with a laser device 400. The positioning device 300 can likewise be moved in the different directions and easily pivoted. The laser device comprises, for example, a Neodym YAG laser to generate light in the near-infrared or via frequency doubling in the visible range of the spectrum. Other types of laser can also be used here, for example, diode lasers, helium-neon lasers or dye lasers. The beam generated by the laser 400 is focused via an optical system 500 on the organic semiconductor element and in particular on the light-emitting layer sequence within the semiconductor element. With the focus in one of the partial layers of the organic semiconductor element, the light-emitting layer sequence is heated and thermally destroyed. The focal point can lie both in the electrodes as well as also in partial layers of the organic LED stack.

Through the thermal heating areas are now selectively destroyed so that when operating the semiconductor element they no longer show any electroluminescence. In operation visible structures can thus be generated in the semiconductor element. During the structuring the laser is used, depending on the desired power or the structuring to be made, in a pulsed or in a continuous mode of operation. It must thereby be ensured that the energy of the laser deposited in the light-emitting layers leads only to a selective and local destruction in the desired areas of the light-emitting organic layer. The control of the laser 400 to generate a structure within the semiconductor element is carried out via the computer 200 and the different positioning devices 100 and 300. This moves along the x or z direction until the desired structure has been completed.

In addition there is also the possibility of replacing the optical system 500 with a moveable mirror optical system. This can be operated, for example, by piezoelectric elements, through which a very rapid alignment of the light beam occurs. Since the focal point of the light within the semiconductor element can be displaced through a strong movement, it is expedient to also move the positioning stage 100. Large-area structures can thus be realized on the organic semiconductor element particularly quickly. Through the control by means of the computer 200, different structures can be generated in a flexible manner and without additional masks.

Furthermore, a structuring can also be carried out via an optical imaging system. Thus, for example, the optical system 500 can be equipped with a shadow mask showing the desired structure. An image of the shadow mask is then focused with the aid of an additional optical system onto the semiconductor element 10 and in particular into the organic layer of the semiconductor element 10.

With the methods shown here very flexible structurings of organic light-emitting diodes can be generated in a simple manner even after the completion of the same. No complex masks and additional photolithographic processes are necessary to this end. The method shown is therefore also suitable for generating small or miniature series of organic light-emitting diodes. In particular individual organic semiconductor elements can also be realized in different sizes.

1. A method for structuring electroluminescent organic semiconductor elements, comprising:
providing an electroluminescent organic semiconductor element with a first electrode and a second electrode and an organic light-emitting layer arranged between the first and second electrode; and
selectively destroying areas of the organic layer by means of thermal action on the organic layer to generate a structured semiconductor element.

2. A method according to claim 1, wherein the organic light-emitting layer comprises at least one first light-emitting partial layer and a second partial layer, at least one of the partial layers being selectively destroyed in areas for a structuring.

3. A method according to claim 1, wherein selectively destroying occurs in that a first organic compound of the organic layer is converted by means of the thermal action into a second compound not capable of luminescence.

4. A method according to claim 1, wherein selectively destroying is carried out by focusing a light beam on the organic light-emitting layer.

5. A method according to claim 4, wherein a wavelength of the light beam lies in the visible wavelength spectrum.

6. A method according to claim 4, wherein a wavelength of the light beam lies in the infrared or in the ultraviolet wavelength spectrum.

7. A method according to claim 4, wherein the light beam is moved during the selective destruction to generate a structure in the organic light-emitting layer.

8. A method according to claim 4, wherein the light beam is generated continuously during the selective destruction of areas of the organic light-emitting layer.

9. A method according to claim 4, wherein the light beam is generated in a pulsed manner during the selective destruction of areas of the organic light-emitting layer.

10. A method according to claim 4, wherein the light beam is generated by a laser.

11. A method according to claim 1, wherein at least one electrode of the electroluminescent organic semiconductor element is transparent to light.

12. A method according to claim 1, wherein the organic semiconductor element is moved during the selective destruction to generate the structure in the organic light-emitting layer.

13. A method according to claim 1, wherein a focal point in the organic light-emitting layer has a diameter in the range of 10 to 300 μm during the selective destruction.

14. A method according to claim 1, wherein at least one electrode of the first and second electrode of the electroluminescent semiconductor element is produced in an unstructured manner.

15. A method according to claim 1, wherein the light beam is focused at least in part by the electrodes.

16. A method according to claim 1, wherein a selective destruction of areas of at least one of the electrodes is carried out by means of thermal action.

17. An electroluminescent organic semiconductor element, comprising:
a first electrode and a second electrode for charge-carrier injection; and at least one organic light-emitting layer arranged between the first and second electrode;
wherein the element is characterized in that at least partial areas of the organic light-emitting layer are selectively destroyed.

18. A semiconductor element according to claim 17, wherein the layer comprises at least one first light-emitting partial layer and at least one second partial layer, at least one of the partial layers being destroyed.

19. A semiconductor element according to claim 17, wherein the partial areas destroyed through thermal action have an organic compound that does not show any luminescence.

20. A semiconductor element according to claim 17, wherein in addition at least partial areas of the first and/or second electrode.

21. An arrangement for structuring an electroluminescent organic semiconductor element, comprising:
a positioning device with a receiving device for at least one electroluminescent organic semiconductor element; a holding device with an illuminating means for emitting a directed light beam; and
a deflection device between the illuminating means and the positioning device, for deflecting the light beam onto the at least one electroluminescent organic semiconductor element; wherein a focal point of the directed light beam lying in a layer of the organic semiconductor element for the selective destruction of partial areas of the layer by means of thermal action.

22. An arrangement according to claim 21, wherein the illuminating means includes a laser device.

23. An arrangement according to claim 22, wherein a Neodym:YAG laser is provided with light in the infrared spectrum or in the green spectrum.

24. An arrangement according to claim 21, wherein the positioning device is arranged in a movable manner essentially perpendicular to the light beam along at least one direction.

25. An arrangement according to claim 21, wherein the deflection device comprises a focusing device for focusing the directed light beam onto the layer of the organic semiconductor element.

26. An arrangement according to claim 21, wherein the deflection device comprises at least one moveable mirror device through which the focal point of the directed light beam is deflected.

27. An arrangement according to claim 21, wherein the focal point of the directed light beam lies in a light-emitting partial layer of the organic layer.

28. An arrangement according to claim 21, wherein the layer comprises at least one of the two electrodes.
